(19) United States
(12) Patent Application Publication
(10) Pub. No.: US 2018/0355478 A1
(43) Pub. Date: Dec. 13, 2018

(54) METHODS FOR METAL-ORGANIC CHEMICAL VAPOUR DEPOSITION USING SOLUTIONS OF INDIUM-ALKYL COMPOUNDS IN HYDROCARBONS

(71) Applicant: Umicore AG & Co. KG, Hanau-Wolfgang (DE)

(72) Inventors: Jörg KOCH, Dautphetal (DE); Oliver BRIEL, Alzenau (DE)

(21) Appl. No.: 15/778,274

(22) PCT Filed: Nov. 24, 2016
(86) PCT No.: PCT/EP2016/078705

§ 371 Date: May 23, 2018

(30) Foreign Application Priority Data
Nov. 25, 2015 (EP) 15196340.2

(51) Int. Cl. C23C 16/40; C30B 25/02; C23C 16/448; C07F 5/00

(52) U.S. Cl. CPC C23C 16/407; C07F 5/00; C23C 16/4481; C30B 25/02

(57) ABSTRACT

The invention relates to methods for producing an indium-containing layer by metal-organic vapor phase deposition, wherein the indium-containing layer is generated on a substrate in a reaction chamber, wherein the indium is delivered to the process in the form of an indium-containing precursor compound with the formula InR₃, wherein the radicals R, independently of one another, are selected from alkyl radicals with 1 to 6 C atoms, characterized in that the delivery of the indium-containing precursor compound takes place in a solution that contains a solvent and the indium-containing precursor compound dissolved therein, wherein the solvent has at least one hydrocarbon with 1 to 8 carbon atoms.

The invention also relates to a solution consisting of a compound of formula InR₃, wherein R are selected independently of one another from alkyl radicals with 1 to 6 C atoms, and at least one hydrocarbon having 1 to 8 carbon atoms, uses of the solution for producing an indium-containing layer by metal-organic vapor deposition, and devices for executing the method.

The invention relates to methods for producing an indium-containing layer by metal-organic vapor phase deposition, wherein the indium-containing layer is generated on a substrate in a reaction chamber, wherein the Indium-containing precursor compound is delivered in a solution. The invention also relates to the solutions, the use of such solutions, and devices for executing the method.

### PRIOR ART

Metal-organic vapor phase deposition, and especially metal-organic vapor phase epitaxy, are important methods for generating thin layers of metals or metal compounds on substrates. The methods are used in the semiconductor industry in particular. In this process, organometallic compounds, optionally in combination with additional reactive compounds, are introduced into processing chambers where, under reduced pressure or normal pressure, a reaction takes place on the surface of heated substrates, leading to deposition of the layer. These methods were developed in the 1970's and 1980's, and have undergone continuous improvement since that time. Thus, today it is possible to deposit a large number of semiconductor crystals, amorphous layers, and metallic compounds on substrates. A review may be seen, for example, in the “Handbook of Thin Film Deposition—Processes and Technologies,” 2nd Edition 2001, editor: Krishna Seshan, Chapter 4, pp. 151-203, by J. Zilko.

For producing indium layers, indium-alkyl compounds are usually used as precursor compounds. In the prior art, solid trimethylindium is often used; in the solid state, this has an adequate vapor pressure and produces scarcely any impurities or unwanted doping in semiconductor layers. Solid trimethylindium is often furnished in stainless steel cylinders for this purpose. These are equipped with at least one gas inlet and gas outlet. An inert carrier gas (primarily hydrogen or nitrogen) is introduced through the gas inlet and comes into contact with the solid TMI in the cylinder, and thus becomes enriched in the carrier gas. The mass throughput of TMI in the gas phase that is achieved at the gas outlet depends, among other things, upon the carrier gas flow rate, the temperature of the TMI, and the pressure.

Such methods are associated with numerous problems. Trimethylindium is a solid with a melting point of 88° C. TMI is pyrophoric, which means that it reacts violently with oxygen at room temperature and ambient air. Handling TMI, especially in the liquid phase, is problematic, since introduction of air into closed vessels with TMI can lead to explosions. This interferes not only with the handling of TMI during the process, but also with the manufacturing, transport, storage, filling of the equipment, metering, or removal and disposal of process residues.

Another disadvantage is that the quantity of the solid indium compound that passes into the vapor phase per unit time is small and cannot be increased at will. Therefore, the growth rate in the production of indium-containing layers by vapor-phase deposition is highly limited.

An additional drawback is that the quantity of gaseous indium released from solid precursor compounds is difficult to measure and adjust continuously. For example, the release rate depends upon the surface area, which changes during the evaporation process.

In the methods with solid TMI it is also disadvantageous that not all of the TMI can be utilized, since optimal and uniform saturation of the vapor phase can no longer be achieved at low filling levels. Another drawback is that in this method, after the TMI is consumed, the vessel containing the TMI, usually a stainless steel cylinder, must be emptied and refilled in a complicated intermediate step, to guarantee uniform Introduction of indium. This means that, overall, the known methods are complicated and take a relatively long time.

To solve such problems, Fannin at al., 1994 (“Constant indium delivery from trimethylindium-hexadecane slurry”; 1994, J. Electron. Mat., 23, 2, pages 93 to 96) suggests introducing the TMI into the process from a suspension. Here, the authors describe a method in which solid TMI is supplied as a suspension in N,N-dimethyldodecylamine. The suspension is evaporated in a bubbler and mixed with a carrier gas. However, the use of such hetero-organic compounds is problematic, since the amine compound or degradation products thereof enter the vapor phase and can induce undesirable side reactions in the process chamber, which can result in doping or contamination of the coating. This is all the more true since TMI forms a complex with the solid. In addition, the problems of handling solid TMI are also not solved with such a suspension.

Alternatively, the authors suggest supplying solid TMI in the form of a suspension in a high-boiling compound, viz., hexadecane. Here also, a bubbler is used to release gaseous TMI and hexadecane. Even this does not solve the fundamental problems in the handling of solid, pyrophoric TMI. In addition, it is generally disadvantageous that the power consumption in the evaporation of such high-boiling liquids is relatively high, since special equipment, such as bubblers, and a relatively high temperature are required. Since TMI and hexadecane exist and are consumed in different phases, continuous release of TMI over long time periods is not possible, and the quantity of gaseous indium released from the solid is low. Thus, overall, the problems with the handling of pyrophoric TMI are, at most, partially solved.

DE 10 2013 225 632 A1 describes a method for metal-organic vapor phase deposition in which additional hydrocarbons, which react at elevated temperatures and cause doping of the product with carbon, are introduced into the process chamber. To achieve the required breakdown of the hydrocarbons into free methyl radicals, high reaction temperatures above 1000° C. and up to 1200° C. are necessary. A similar method is described in U.S. Pat. No. 6,284,042 B1. According to this document as well, a hydrocarbon is added separately from the organometallic compound, after which a chemical reaction takes place in the reaction chamber at high temperature, with decomposition of the hydrocarbons, leading to doping of the product with carbon.

Overall, there is a need for improved methods of producing indium-containing layers by metal-organic vapor phase deposition that overcome the above-described disadvantages.

### OBJECT OF THE INVENTION

The invention is based upon the object of providing methods, means, applications, and devices that overcome the above-described disadvantages. In the process, methods for producing indium-containing layers by metal-organic vapor phase deposition—especially, metal-organic epitaxy—that are simpler, more useful for the process, and more efficient, should be provided. The risks associated with the handling of solid trimethylindium should be reduced or avoided. The indium introduced into the process should be easy to handle and to meter. The method should make it possible to regulate a high concentration and a high mass throughput of indium or an indium-containing precursor compound in the vapor phase and in the reaction chamber. The method should be efficient with regard to the materials used and the labor and power expenditures. In the process, high-purity, indium-containing, connecting semiconductor layers that do not contain any unwanted dopants or impurities should be produced. The method should also enable better utilization of the starting substances.

### DISCLOSURE OF THE INVENTION

Surprisingly, the object upon which the invention is based is solved by methods, solutions, applications, and devices according to the claims.

The subject matter of the invention is a method for producing an indium-containing layer by metal-organic vapor phase deposition, wherein the indium-containing layer is generated on a substrate in a reaction chamber, wherein the indium is delivered to the process in the form of an indium-containing precursor compound with the formula InR₃, wherein the radicals R, independently of one another, are selected from alkyl radicals with 1 to 6 C atoms, characterized in that the delivery of the indium-containing precursor compound takes place in a solution that contains a solvent and the indium-containing precursor compound dissolved therein, wherein the solvent has at least one hydrocarbon with 1 to 8 carbon atoms.

The metal-organic vapor phase deposition (MOCVD, “metallo-organic chemical vapor deposition”) is a coating method from the group of chemical vapor deposition (CVD) methods, in which the deposition of a solid layer on a substrate takes place from the chemical vapor phase using a metal-organic precursor compound (precursor). Surprisingly, it was determined that there is no integration of higher quantities of carbon or oxygen compared with conventionally deposited layers if the indium-containing precursor compound is used in combination with a solvent as described above.

In a preferred embodiment, the metal-organic vapor phase deposition is a metal-organic vapor phase epitaxy (MOVPE, standing for “metal organic vapor phase epitaxy,” and also called “organo-metallic vapor phase epitaxy,” OMVPE). Whereas any deposition on a substrate is possible with MOCVD, MOVPE is an epitaxy method and thus relates to crystalline growth on a crystalline substrate. The methods, especially MOVPE, are especially used for deposition of semiconductor materials.

According to the invention, a solution of an alkyl-indium compound (precursor compound) in a solvent is used. Here, the term “solution,” as usually used, means that the precursor compound is actually dissolved in the solvent, and not just suspended. Thereby, the solution, at least at the beginning, and thus upon introduction into the process and/or before transfer into the vapor phase, is present in liquid form. During the process, the solution is converted to the vapor phase, which can take place before or during the introduction into the reaction chamber. It is particularly preferred for the solution to consist of the indium-containing precursor compound and the solvent.

According to the invention, the indium-containing precursor compound used is an alkyl-indium compound of formula InR₃. The radicals R are selected independently of one another from alkyl radicals with 1 to 6 C atoms—especially 1 to 3 C atoms—in particular, methyl and/or ethyl. For example, the precursor compound is selected from trimethylindium, triethylindium, or ethyldimethylindium. Mixtures of such alkyl-indium compounds may also be used.

In a preferred embodiment, the precursor compound is trimethylindium (TMI). Trimethylindium, according to the prior art, is principally used for producing indium-containing layers by metal-organic vapor phase deposition or epitaxy. TMI is a white solid with a boiling point of 136° C.

The solvent contains at least one hydrocarbon with 1 to 8 carbon atoms. Preferably, the solvent consists of at least one hydrocarbon with 1 to 8 carbon atoms. According to the usual terminology, hydrocarbons are organic compounds consisting exclusively of carbon and hydrogen. Particularly preferably, the solvent consists of a hydrocarbon with 1 to 8 carbon atoms. The hydrocarbons they may be alkanes, aromatics, or alkenes. They may be noncyclic or cyclic hydrocarbons. The alkanes or alkenes may be linear or branched.

In a preferred embodiment, the solvent consists of hydrocarbons with 5 to 8 carbon atoms, which are preferably alkanes or aromatics. Such hydrocarbons generally have boiling points that are only slightly below the boiling point of alkyl-indium compounds. These hydrocarbons have a comparatively high vapor pressure and, therefore, can be evaporated with quite low energy consumption. In addition, the boiling points are not far from those of the alkyl-indium compounds, favoring uniform and complete evaporation of the solution.

In a preferred embodiment, the solvent has at least one alkane. Particularly preferably, the solvent is an alkane or a mixture of alkanes. In this case, the alkane may be selected from methane, ethane, propane, butane, pentane, hexane, heptane, or octane. The alkane is preferably linear or branched. Alkanes are particularly suitable as solvents according to the invention, since they are relatively inert. As a result, even at relatively high reaction temperatures, no undesirable reactions with the solvent, which could, for example, lead to decomposition and introduction of carbon into the layer being deposited, take place in the vapor phase.

Particularly preferably, the solvent is an alkane with 5 to 8 carbon atoms, thus selected from pentane, hexane, heptane or octane, or a mixture thereof. In this process, any isomers whatsoever may be used, for example, n-pentane, isopentane or neopentane; or n-hexane, 2-methylpentane, 3-methylpentane, 2,2-dimethylbutane or 2,3-dimethylbutane. Analogously, all conceivable mixtures of heptane or octane isomers may be used. The use of pentane is particularly preferred.

In a preferred embodiment, the solvent has at least one aromatic. Particularly preferably, the solvent is an aromatic or a mixture of aromatics. For example, the aromatic may be a derivative of benzene substituted with one or two methyl groups or with an ethyl group. The aromatic is preferably selected from toluene, xylene, and benzene. Aromatics are especially suitable, since alkyl-indium compounds are particularly readily soluble in them. Such low-molecular-weight aromatics are also relatively inert and have boiling points only slightly below those of the alkyl-indium compounds. Toluene is preferably used as the solvent. The solubility of TMI in toluene is up to 50 wt %. Therefore, the method can be performed particularly efficiently with a solution of high concentration, and side reactions can be reduced.

Particularly preferably, the solvent is an aromatic with 6 to 8 carbon atoms—especially, toluene, xylene, or benzene. Such aromatics can dissolve TMI in especially large amounts. They also have boiling points that are only slightly below the boiling point of TMI.

The solution is preferably an azeotrope. Alkanes are also preferred as solvents, since they form azeotropes with trimethylindium. During the evaporation of azeotropes, uniform and relatively high concentrations of the components can be established in the vapor phase.

It is preferred in such cases for the solvent to have a higher vapor pressure than the alkyl-indium compound. The boiling point of the solvent in such cases may be below the boiling point of the alkyl-indium compound by at least 10° C., at least 30 SC, or at least 50° C. Preferably the boiling points are not too far apart—preferably by no more than 100° C., or no more than 70° C.—so that efficient joint evaporation can take place. Preferably, the difference in the boiling points of the solvent and alkyl-indium compound is between 10° C. and 100° C.—especially, between 15° C. and 70° C. When TMI, with a boiling point of about 134° C., is used, it is preferred that the solvent have a boiling point in the range of about 0° C. to about 120° C.

Mixtures of the hydrocarbons mentioned may also be used. For example, mixtures of the mentioned alkanes and/or aromatics with 5 to 8 hydrocarbons may be used. It may also be advantageous for technical reasons to use a hydrocarbon that is slightly contaminated with other hydrocarbons, e.g., up to 20 wt %, up to 10 wt %, or up to 5 wt %.

If short-chain hydrocarbons are used, especially with 1 to 4 carbon atoms, the solution may have to be cooled before introducing it into the process. Since this requires additional cooling energy, such embodiments are less preferred.

Preferably, the share of the precursor compound in the solution is at least 2 wt %, at least 5 wt %, or up to 15 wt %. Preferably, the solution contains up to 60 wt % or up to 55 wt % of the precursor compound in dissolved form. In a preferred embodiment, the share of the precursor compound in the solution is between 5 to 60 wt %—preferably, between 15 and 55 wt %. According to the invention, the precursor compound should be completely dissolved. This is advantageous in that, even if only a small part of the precursor compound is present in undissolved form, the composition of the vapor phase could be changed in an adverse way, and, in a continuous process, pipelines and process apparatus may become clogged. With the solutions according to the invention, the problems according to the prior art can be avoided with solid alkyl-indium compounds.

In methods for metal-organic vapor phase deposition, and, especially, metal-organic vapor phase epitaxy, the production of the indium-containing layers takes place in a reaction chamber. A substrate to be coated is located therein and is heated to a high temperature. A gas flow with the indium-containing precursor compound and usually a carrier gas is introduced into the reaction chamber, where the precursor compound in the vapor phase is first broken down, and free radical groups attach to the substrate. Thermally activated, the free radical groups have a certain freedom of movement on the substrate, until the indium atom is incorporated in the layer at a suitable location. The organic radical is desaturated with elemental hydrogen, and a stable, volatile organic compound forms. This residual gas is discharged from the reaction chamber. To this extent, the device according to the invention corresponds to known devices. It is preferred that the solution be converted into the vapor phase before introducing it into the reaction chamber. In a less preferable embodiment, it is also conceivable that the solution not be evaporated until it is introduced into the reaction chamber.

The transfer of the solution into the vapor phase preferably takes place in a process step prior to the reaction in the reaction chamber. Preferably, an evaporator is used for transferring into the vapor phase. In an evaporator, sufficient thermal energy is supplied to a solution to cause evaporation. It is preferred that the solution be converted into the vapor phase using a direct evaporator (2) before introducing it into the reaction chamber (4).

In a preferred embodiment, the evaporator is a direct evaporator. The solution is evaporated immediately and completely in the direct evaporator when it enters the evaporator. In this process, the pressure, temperature, and mass flow rate are set so that the solution is converted into the vapor phase immediately after introduction. The solution also does not collect in a liquid reservoir in the direct evaporator. On the other hand, the evaporation takes place according to the prior art using bubblers from a liquid reservoir, wherein the quantity of liquid evaporated is regulated by the process conditions in the bubbler (pressure, temperature, liquid surface area).

In the direct evaporator, the solution is usually evaporated using an LFC (Liquid Flow Controller) in a heated mixing valve with addition of inert carrier gas. The direct evaporator has a heating device. In this way, thermal energy is supplied to compensate for the evaporative cooling occurring during evaporation. The compact design of the direct evaporator can, among other things, allow installation near the reactor. As a result, higher temperatures can be established without further steps, wherein even precursor compounds with low vapor pressure can be efficiently converted into the vapor phase and introduced into the processing chamber. Direct evaporators are known in the prior art and are commercially available. For example, a CEM system from Bronkhorst AG, Switzerland, or a DirectVapor product from Sempa Systems GmbH, Germany, may be used.

Preferably, the direct evaporator has a temperature of 0° C. to 100° C.—especially, between 10° C. and 50° C.—and/or a pressure of 50 mbar to 1800 mbar. In this process, temperature and pressure are adapted to one another, so that complete evaporation of the solution takes place, and this remains in the vapor phase. In particular, the process conditions are adjusted so that rapid evaporation occurs without liquid or solid residues remaining.

The direct evaporator may have a nozzle. The direct evaporator may be a direct injector (Direct Liquid Injection, DJI). Direct evaporators with nozzles allow continuous, efficient conversion of liquids into the vapor phase.

The control of the mass throughput rates in the process is preferably accomplished using flow regulators and/or valves. The control is preferably electronic.

The quantity of directly evaporated solution is preferably regulated and monitored using a liquid flow regulator. Particularly preferably, the liquid flow regulator is part of the direct evaporator. Such regulators, especially in compact form in connection with the direct evaporator, allow optimal control of the mass throughput rate in response to demand in the reaction chamber.

Preferably, the evaporated solution is mixed with a carrier gas before introduction into the reaction chamber. The carrier gas serves to support transport and prevent condensation effects. Thus it is preferably nonreactive and is inert in the process. The usual carrier gases, such as nitrogen, hydrogen, or inert gases, may be used in this process.

The quantity of carrier gas introduced is preferably regulated and monitored using a gas flow regulator. Particularly preferably, the gas flow regulator is part of the direct evaporator. Such regulators, especially in compact form in connection with the direct evaporator, allow optimal control of the carrier gas in terms of the mass throughput rate of the evaporated solution and the demand in the reaction chamber.

The evaporated solution is preferably mixed with the carrier gas in a mixing chamber. The mixing chamber preferably has a mixing valve. The mixing valve makes it possible to establish exact and uniform concentrations of the components and the indium-containing precursor compound. The mixing chamber is preferably part of the direct evaporator. The evaporation in this process preferably takes place directly in the mixing chamber. This means that the solution is directly evaporated into a chamber in which the gas phase is mixed with an additional phase.

In a particularly preferred embodiment, a direct evaporator having a liquid throughput rate regulator, a gas flow regulator, a mixing chamber, and a mixing valve is used. In this embodiment, the components for controlling the mass throughput rate of the solution and carrier gas, and the components for mixing the gas phases, are integral components of the direct evaporator. A design of this type enables compact, continuous, and efficient preparation of indium precursor compounds in solution for reaction in the reaction chamber.

Preferably, no bubbler is used in the method according to the invention. According to the prior art, corresponding methods are carried out using a bubbler (vapor pressure saturator). A bubbler comprises a vessel that contains the liquid to be evaporated and the solid organometallic precursor compound and through which an inert carrier gas is passed. A disadvantage in such cases is that precise and continuous process control is impossible, or at least relatively laborious, with such a multi-component system containing a solvent, a precursor compound, and an inert carrier gas. On the other hand, the method according to the invention can be performed with a direct evaporator without a bubbler. In direct evaporation, the mixing of the solution with the carrier gas can be better controlled, and the method can be performed continuously over rather long time periods without it being necessary to empty or refill a bubbler.

The conditions in the process chamber are preferably set such that no, or essentially no, parasitic doping with carbon occurs. In this process, the hydrocarbons used as solvents do not react, or only react insignificantly, and do not adversely affect the product. This is possible if the temperatures in the process chamber are not set too high, so that no breakdown of the hydrocarbons into reactive radicals takes place. Preferably, the reaction in the reaction chamber takes place at a temperature that is below 950° C.—more preferably below 900° C., or especially below 800° C. This is especially thereby given, because, for the deposition of indium-containing layers, process conditions are set such that deposition temperatures of less than 900° C. are selected.

The conditions in the method and in the process chamber are set such that no condensation of liquid from the vapor phase takes place before this is conducted out of the reaction chamber. The process conditions, especially pressure and temperature, are adjusted after evaporation of the solution such that the vapor phase is above the dew point. The dew point at a given pressure is the temperature that must be exceeded so that liquid will separate from the vapor phase as a precipitate. The temperature of the gas phase in the reaction chamber with the indium precursor compound is preferably greater than 100° C., more preferably greater than 300° C., or greater than 400° C.

The temperature in the reaction chamber may, for example, be between 100 and 950° C., or between 400 and 900° C.

The solvent and/or the inert carrier gas could be reprocessed and reused after emerging from the reaction chamber. The solvent could be condensed and separated.

According to the invention, it is possible to introduce precursor compounds for the production of indium-containing layers on substrates particularly uniformly and in particularly high mass flow rates into a reaction chamber for metal-organic vapor phase deposition. Then, the layers can be produced on the substrate using known methods. Usually, at least one additional reactive substance is introduced into the reaction chamber—preferably, at least one additional precursor compound. For example, additional reactive substances may be introduced, so as to apply elements of the fifth main group of the periodic table, such as nitrogen, phosphorus, and/or arsenic, or elements of the third main group, such as aluminum or gallium. The products may be multi-layered, and/or the indium-containing layer can have additional elements, thus forming a mixed crystal, or may be doped. Such precursor compounds and methods are known in the prior art. For example, reference is made in this connection to Stringfellow, Gerald B., “Organometallic Vapor-Phase Epitaxy: Theory and Practice,” 1989, published by Academic Press, ISBN 10: 0126738408.

The method according to the invention can be used for preparing indium-containing layers. The layers may contain indium compounds or elemental indium. In this process, known methods of CVD (Chemical Vapor Deposition) may be used, wherein, for example, layers may be prepared from ITO (indium tin oxide) or IGZO (indium gallium zinc oxide).

In a preferred embodiment, especially in the case of MOVPE, the method is used for producing semiconductor crystals. The method and the process may be used, for example, for producing lasers, photodetectors, solar cells, phototransistors, photocathodes, transistors, detectors, or modulators.

The object of the invention is also a solution, consisting of
(a) 5 to 60 wt %—especially, 15 to 55 wt %—of a compound of formula InR₃, wherein the R are selected independently of one another from alkyl radicals with 1 to 6 C atoms, wherein the compound is preferably trimethylindium, and
(b) 40 to 95 wt %—in particular, 45 to 85 wt %—of at least one hydrocarbon, which has from 1 to 8 carbon atoms.

Preferably the solution consists of 5 to 60 wt % of trimethylindium and 40 to 95 wt % of an alkane or an aromatic that has from 1 to 8 carbon atoms—preferably, 5 to 8 carbon atoms. Preferably the solution consists of 5 to 15 wt % of trimethylindium and 85 to 95 wt % of an alkane that has 5 to 8 carbon atoms or of 15 to 60% trimethylindium and 40 to 85 wt % of an aromatic with 6 to 8 carbon atoms.

The preferred solutions correspond to those described above, which can be used in the method according to the invention. To avoid repetitions, specific reference is made to the above statements on composing the solution, and especially on selecting the alkyl-indium compounds and solvents.

Another object of the invention is the use of the solution according to the invention for producing an indium-containing layer—especially semiconductor layers—by metal-organic vapor phase deposition. In these processes, the use takes place correspondingly as described above for the method. To avoid repetitions, reference is made to the above statements on the method.

Another object of the invention is a device for performing the method according to the invention, comprising
(A) liquid feed lines for delivering the solution,
(B) a liquid flow regulator for metering the solution,
(C) means for delivering the inert carrier gas,
(D) a gas flow regulator for metering the carrier gas,
(E) a direct evaporator with a heating device for evaporating the solution and a mixing chamber for mixing with the carrier gas,
(F) a reaction chamber for producing an indium-containing layer on a substrate, and
(G) gas feed lines for delivering the gas phase into the reaction chamber.

The regulators (B) and (D) are preferably components of the direct evaporator.

For the further design of the device, reference is made to the above statements on process control and to the following example.

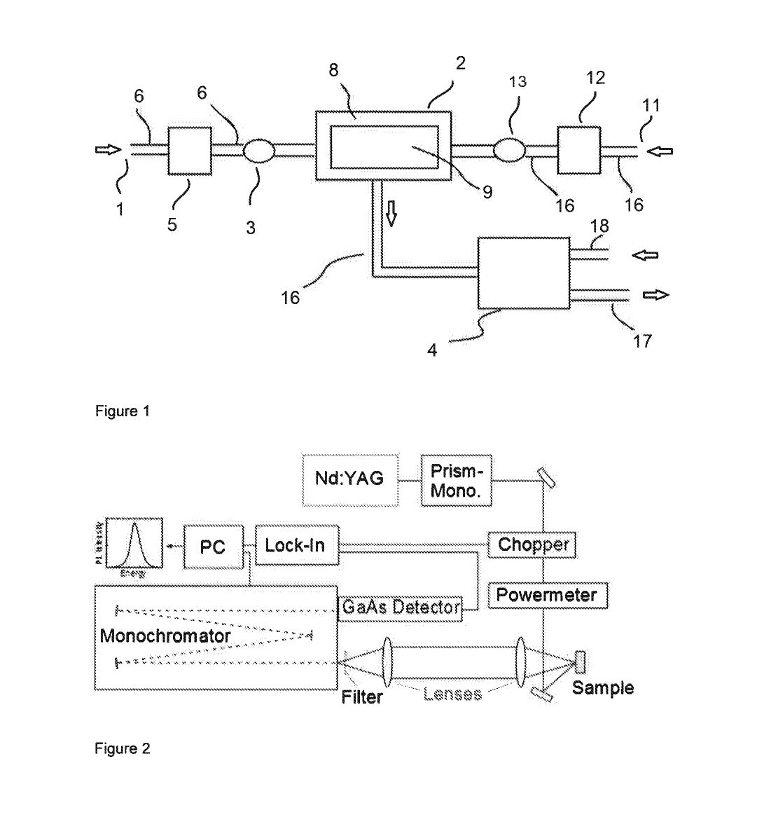

FIG. 1 shows by way of example a device according to the invention for performing the method of the Invention.

FIG. 1 shows by way of example and schematically a device for performing the method of the invention. The solution is introduced into the method through an intake 1. In this process, a liquid solution of trimethylindium (10 wt-%) in C5- to C8-alkanes or in C6- to C8-aromatics could be used. The solution is conducted over liquid feed lines 6 into a direct evaporator 2, which has a heating device 8 and a mixing chamber 9. The volume of liquid is controlled and measured using a liquid flow rate regulator 5, which is a component of the direct evaporator or can be connected in front of this. In addition, the metering can be performed using a valve 3. In a direct evaporator 2, the solution is completely converted into the gas phase by setting suitable process parameters, such as temperature and pressure, wherein a temperature of 20° C. to 80° C. is preferably set. The evaporation in this process preferably takes place directly in the mixing chamber, which is an integral part of the direct evaporator. The solution is mixed in the mixing chamber 9 with an inert carrier gas that is introduced through an inlet 11 and gas feed lines 16. The quantity of the carrier gas is controlled with gas flow regulator 12 and valve 13. Preferably, a direct evaporator 2 is used, which has the liquid flow rate regulator 5, the gas flow regulator 12, the mixing chamber 9, and the mixing valve 13 as integral components. The gas phase is introduced from the mixing chamber 9 over gas feed lines 16 into the reaction chamber 4—optionally, over suitable additional process steps such as pressure stages. By way of known measures, the reaction and deposition of indium or the incorporation of indium into the mixed crystal on the surface of the heated substrate takes place in the reaction chamber 4. The reaction gas and the carrier gas flow through the reactor and are discharged into the exhaust gas system over gas outlet line 17. Additional reactive substances in the gas phase can be supplied to the reaction chamber over one or more additional gas feed lines 18, so as to produce coatings or mixed crystals from multiple elements.

The invention solves the its underlying problem. An improved, efficient, and relatively simple method for continuous production of indium-containing layers by metal-organic vapor phase deposition or epitaxy is proposed. Risks in the handling of solid pyrophoric alkyl-indium compounds are avoided or distinctly reduced by avoiding the use of a solution. Consequently, the explosion and ignition hazards are already reduced for the manufacturer of the alkyl-indium compound, who can prepare, store, and transport this directly in solution. Hazards are also avoided in metering, in filling the unit, and in executing the process.

The use of solutions in low-boiling liquids makes possible a marked increase in the mass flow rate of the indium compound in the gas phase. In contrast, high mass flow rates cannot be achieved in methods of the prior art with bubblers and solid alkyl-indium compounds, even in the form of suspensions, since the saturation of the gas phase with allylindium compounds is thermodynamically limited by the solid aggregation state and the dimensions of the bubbler. The use of solutions also allows for more accurate metering and flexible, rapid adjustment of the solution volume introduced to the process requirements. An additional advantage is that the regular replacement of solid cylinders with residues of pyrophoric alkyl-indium compounds necessary according to the prior art is not required. Therefore, the method can be performed continuously over long time periods. Because of the use of solutions, complete introduction of the starting substances into the process can take place, which is desirable for financial and environmental reasons. An additional advantage is that the solvent does not react and, therefore, can be processed and reused. The method is also financially advantageous, because low-boiling alkanes or aromatics are available in large quantities and are therefore inexpensive.

### EXAMPLES

Deposition Conditions:

The depositions were carried out in an Aixtron AIX 200-GFR reactor system. Hydrogen (H2) with a flow rate of 6800 mL/min was used as the carrier gas. The depositions were carried out at 50 mbar. The temperature was calibrated based upon a comparison with the melting point of the aluminum-silicon eutectic (melting point 577° C.).

A solution of trimethylindium in toluene with a concentration of 30 mol % (also referred to as liquid in the following), trimethylgallium (DockChemicals), and trimethylaluminum (EMF) served as group III sources; tert-butylphosphine (DockChemicals) served as group V sources.

Two different layer types were deposited:
1) ((Al_{0.3}Ga_{0.7})_{0.5}In_{0.5})P double heterostructure with a growth rate of 1.53 μm/h. The ratio of group V to group III precursors was 96; the deposition temperature was 685° C. The layer thus deposited was used for the photoluminescence measurements.
2) ((Al_{0.7}Ga_{0.3})_{0.5}In_{0.5})P multilayer structure for SIMS measurements. In this connection, different temperature profiles, as well as group V to group III precursor ratios were examined: V/III=25, 50 and 100, T=625, 655, 670, 685° C. The layer thus deposited was used for SIMS measurements (secondary ion mass spectrometry).

Photoluminescence Measurements:

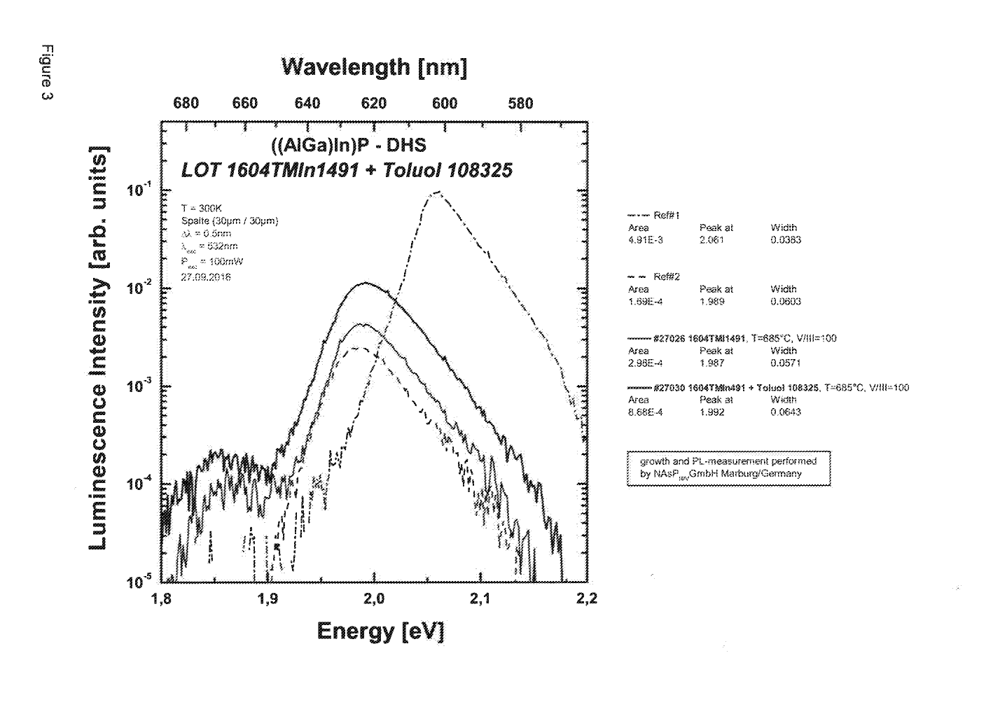

The layers was examined for their photoluminescence by means of stimulation with an Nd-YAG laser. Two samples, which are used at the firm NAsP as a reference, served as a comparison. Their photo properties serve as upper or lower limits and are used for qualifying the samples. The measurement configuration is shown in FIG. 2.

Impurities and crystalline defects in the layers can be identified in photoluminescence spectra: The broader the photopeak (FWHM in Table 1) or the lower the radiated photo intensity (i.e., integrated intensity in Table 1), the worse the quality of the layer examined.

FIG. 3 shows photoluminescence spectra of the sample obtained using liquid In (27030, thick solid black line, above), of a comparison sample with pure trimethylindium as a comparative example (27026, thin solid black line), and of the two reference samples (Ref 1 and Ref 2, with dot-dashed or dotted lines).

As can be seen from FIG. 3 and Table 1, the layer which was deposited from liquid In lies, in terms of its properties, between (integrated intensity) or close to the two reference values (FWHM or half-width) and is therefore suitable for use as a precursor for indium-containing layers.

TABLE 1
Evaluation of the photoluminescence measurement of the
AlGalnP-DH structures

| | 27026 | 27030 | Ref 1 | Ref 2 |
|---|---|---|---|---|
| Integrated | 2.98 * 10⁻⁴ | 8.68 * 10⁻⁴ | 4.91 * 10⁻³ | 1.69 * 10⁻⁴ |
| Intensity [a.u.] | | | | |
| λ_{Peak} [eV] | 1.987 | 1.992 | 2.061 | 1.992 |
| FWHM [eV] | 0.0571 | 0.0643 | 0.0383 | 0.0603 |

SIMS Measurements:

Secondary ion mass spectrometry provides information as to which and how many Impurities are present in a sample.

The layers for the SIMS measurements (layer 2) were produced by means of depositions being effected on a substrate, with, for one, the deposition temperature for the depositions being gradually increased and, for another, the ratios of the concentrations of the group V- to group III sources being varied.

This means that a layer structure with 9 layers was deposited, each differing in their deposition temperature and the ratios of the group V to group III sources.

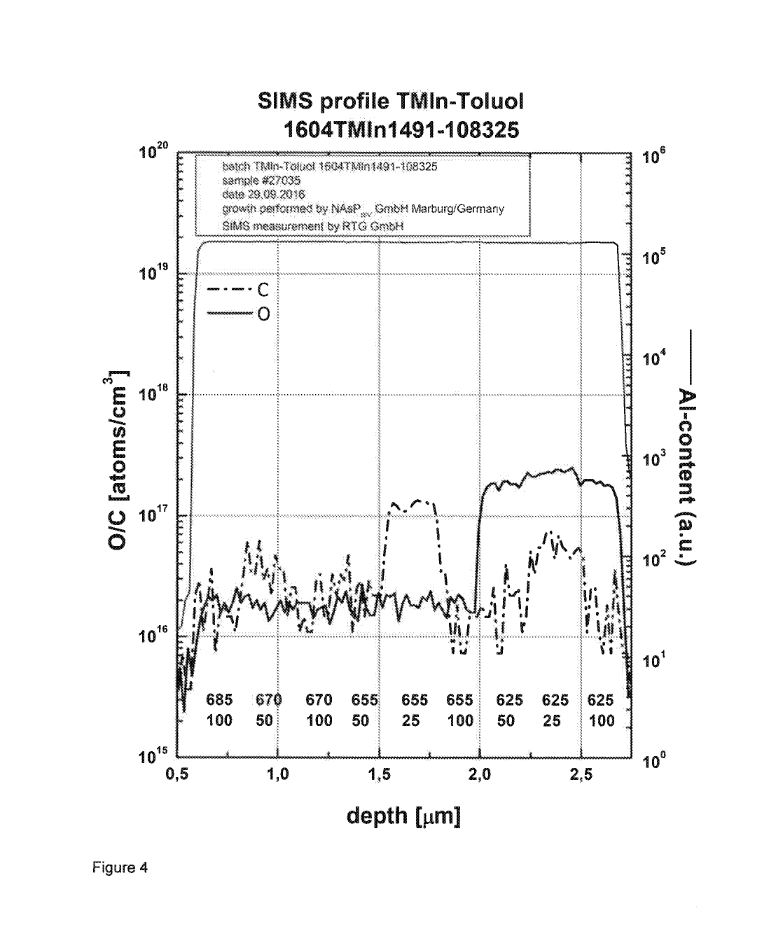

These ratios are shown as the bottom row of figures in the diagram in FIG. 4 (values of 100, 50, 100, 50, 25, 100, 50, 25, 100); the deposition temperatures are shown in the row of figures above.

For example, it can be seen that the progression of the black curve on the right-hand side has a high plateau, which is formed at deposition temperatures of 625° C., independently of the ratio of group V to group III sources.

With the aid of the oxygen/carbon integration rate, the person skilled in the art can, depending upon the group V/group III source ratios and the deposition temperatures, make statements concerning the purity of the layers and, therefore, the precursors used.

FIG. 4 shows the SIMS measurement of a sample obtained by using liquid In as an indium source. The conditions for layer deposition are provided above.

The oxygen content (solid line) and carbon content (dotted line) are shown in the SIMS spectrum. The layers examined were effected at varying temperatures (top row of figures in ° C.) and with varying group V to group III ratios (bottom row of figures). Surprisingly, no conspicuous integration of carbon or oxygen into the layers could be observed by means of SIMS measurements. The increased carbon integration at 655° C. and a ratio of 25 can be attributed to an insufficient disintegration of the group III precursors, an observation which is often made for depositions with trimethylindium. The increased oxygen integration in the temperature range of 625° C. can be attributed to oxygen impurities which were introduced from the group V precursors.

### REFERENCE SYMBOLS

1 Solution inlet
2 Direct evaporator
3 Valve
4 Reaction chamber
5 Liquid flow rate regulator
6 Liquid feed lines
8 Heating apparatus
9 Mixing chamber
11 Carrier gas feed
12 Gas flow rate regulator
13 Valve
16, 18 Gas inlet lines
17 Gas outlet line

1.-15. (canceled)

16. A method for producing an indium-containing layer by metal-organic vapor phase deposition, wherein the indium-containing layer is generated on a substrate in a reaction chamber, wherein the indium is delivered to the process in the form of an indium-containing precursor compound with the formula InR₃, wherein the radicals R, independently of one another, are selected from alkyl radicals with 1 to 6 C atoms,
wherein the indium-containing precursor compound is delivered in a solution that contains a solvent and the indium-containing precursor compound dissolved therein, wherein the solvent has at least one hydrocarbon with 1 to 8 carbon atoms.

17. The method according to claim 16, wherein the metal-organic vapor deposition is a metal-organic vapor epitaxy.

18. The method according to claim 16, wherein the precursor compound is trimethylindium.

19. The method according to claim 16, wherein the solvent has at least one alkane and/or an aromatic.

20. The method according to claim 16, wherein the solvent consists of hydrocarbons with 5 to 8 carbon atoms, wherein the solvent is preferably pentane, hexane, heptane, octane, toluene, benzene, xylene, or a mixture thereof.

21. The method according to claim 16, wherein the share of the precursor compound in the solution is 5 to 60 wt %.

22. The method according to claim 16, wherein the solution is converted into the vapor phase using a direct evaporator before introducing it into the reaction chamber.

23. The method according to claim 22, wherein the direct evaporator has a temperature of 0° C. to 100° C.—preferably, between 10° C. and 50° C.—and/or a pressure of 50 mbar to 1200 mbar.

24. The method according to claim 22, wherein the solution is converted into the vapor phase before introducing it into the reaction chamber.

25. The method according to claim 24, wherein the direct evaporator has a mixing chamber in which the vapor phase is mixed with the carrier gas.

26. The method according to claim 22, wherein the direct evaporator has a liquid flow rate regulator, a gas flow rate regulator, a mixing chamber, and a mixing valve.

27. The method according to claim 16, wherein at least one additional reactive substance is delivered into the reaction chamber.

28. (canceled)

29. (canceled)

30. (canceled)
